(19) United States
(12) Patent Application Publication
(10) Pub. No.: US 2010/0186997 A1
(43) Pub. Date: Jul. 29, 2010

(54) CRIMPED SOLDER ON A FLEXIBLE CIRCUIT BOARD

(75) Inventor: Brian VICICH, Prospect, KY (US)

Correspondence Address: SAMTEC INCORPORATED;C/O KEATING & BENNETT, LLP, 1800 Alexander Bell Drive, SUITE 200, Reston, VA, 20191, US

(73) Assignee: SAMTEC INC., New Albany, IN (US)

(21) Appl. No.: 12/695,564

(22) Filed: Jan. 28, 2010

Related U.S. Application Data
(60) Provisional application No. 61/148,138, filed on Jan. 29, 2009.

(51) Int. Cl. H05K 1/00; H05K 3/00

(52) U.S. Cl. 174/254; 29/844

(57) ABSTRACT

A method for attaching a fusible member to a flexible circuit board includes providing the flexible circuit board including an electrode and a hole near each other, placing the fusible member in the hole, and deforming the fusible member to fix the fusible member to the flexible circuit board. A flexible circuit board includes an electrode, a hole, and a fusible member fixed to the hole and arranged to establish an electrical connection with the electrode when the fusible member is fused to the electrode.

### BACKGROUND OF THE INVENTION

1. Field of the Invention

The present invention relates to attaching solder to a flexible circuit board, and more specifically, the present invention relates to crimping solder to a flexible circuit board.

2. Description of the Related Art

It is known to connect rigid printed circuit boards to an electronic device so that electrical connections are established between the rigid printed circuit boards and the electronic device. Rigid printed circuit boards provide a flat surface on which electrical connectors can be soldered so that the electrical connections between the rigid printed circuit boards and the electronic device can be provided. Solder locations on the rigid printed circuit boards, to which the electrical connectors can soldered, are typically arranged in severely limited, repetitive patterns that have a fixed height and that cannot be variable because the rigid printed circuit boards cannot be bent.

It is also known that electrical connectors typically include stamped and formed copper-alloy contacts and plastic housings that are assembled together. The electrical connectors are also rigid and cannot be bent. The electrical connectors have geometries that have limited complexity and that are limited in ability to connect to multiple heights because the electrical connectors cannot be bent. Further, the length of the copper-alloy contacts in the electrical connectors limits the minimum height of the electrical connectors.

Electrical connectors are typically connected to rigid printed circuit boards by using electrical contacts. Typically, the electrical contacts are soldered to the rigid printed circuit board by batch processing the solderable components (including the electrical contacts and other components), by hot-bar soldering, or by ultrasonic welding. Because rigid printed circuit boards and electrical connectors cannot be bent, more effort must be put into designing the printed circuit boards and the electrical connectors to ensure that proper electrical connections can be established between the printed circuit board and the other electronic devices.

It is known to use flexible circuit boards instead of rigid printed circuit boards. Unlike rigid printed circuit boards, flexible circuit boards are easily bent. Flexible circuit boards do not require electrical contacts, which are typically formed of a copper alloy, or plastic housing, to provide electrical connections. Flexible circuit boards use a laminated structure with alternating conductor/insulator layers that can have very complex geometries, down to the nano-scale. Because flexible circuit boards can be bent, flexible circuit boards are easier to design because electrical connections can be established at nearly any desirable interval and height. Flexible circuit boards can be used in applications where, due to size constraints, a rigid printed circuit board that is thicker cannot be used. However, because of the thinner construction of flexible circuit boards, it is difficult to establish electrical connections between a flexible circuit board and an electronic device.

There are many known methods of establishing electrical connections between a flexible circuit board and an electronic device. For example, it is known to:

1) solder or crimp metal posts to terminals of a flexible circuit board, where the metal posts are then soldered to the electronic device;

2) hot-bar solder a flexible circuit board directly to a rigid printed circuit board;

3) form a hybrid rigid-flex circuit board where the flexible circuit board is laminated in between layers of a printed circuit boards;

4) overmold the ends of a flexible circuit board to provide recessed terminals;

5) provide sculpted flexible circuit boards in which metal posts are embedded in raised portions of the flexible circuit board; and

6) ultrasonically weld flexible circuit boards in which ends of the flexible circuit board are welded to external connectors that are similar to traditional circuit board connectors.

However, each of these conventionally electrical connections used for flexible circuit boards require the addition of an electrical contact or other connection structure to the end of the flexible circuit board. This addition increases the number of required manufacturing steps, while also raising costs and the number of required components. Thus, there is a need in the art for an electrical connection system for a flexible circuit board that can be performed in a shorter time and with fewer parts.

### SUMMARY OF THE INVENTION

To overcome the problems described above, preferred embodiments of the present invention provide a method of manufacturing a flexible circuit board by deforming a fusible member to fix the fusible member to a hole in the flexible circuit board and provide a flexible circuit board with a deformed fusible member fixed to a hole in the flexible circuit board.

According to a preferred embodiment of the present invention, a method for attaching a fusible member to a flexible circuit board includes providing the flexible circuit board including an electrode and a hole near each other, placing the fusible member in the hole, and deforming the fusible member to fix the fusible member to the flexible circuit board.

The fusible member is preferably solder. The deforming step is preferably performed by crimping the fusible member. A portion of the flexible circuit board surrounding the hole is preferably removed prior to the step of placing the fusible member into the hole. The method for attaching a fusible member to a flexible circuit board preferably further includes forming a conductive layer in an inner surface of the hole. The conductive layer is preferably copper or a copper alloy. The electrode is preferably a conductive trace or a conductive plane. During the step of deforming, a mass of the fusible member is preferably formed on at least one side of the flexible circuit board. The electrode is preferably located on the surface of the flexible circuit board or within the flexible circuit board.

Accordingly to a preferred embodiment of the present invention, a method for electrically connecting a flexible circuit board to a target substrate includes providing a target substrate, providing a flexible circuit board with a fusible member, and fusing the fusible member to form a joint between the flexible circuit board and the target substrate so that an electrical connection is formed between the electrode and the target substrate, where the step of providing a flexible circuit board with a fusible member includes providing the flexible circuit board, the flexible circuit board including an electrode and a hole near each other, placing the fusible member in the hole, and deforming the fusible member to fix the fusible member to the flexible circuit board.

According to a preferred embodiment of the present invention, a flexible circuit board includes an electrode, a hole, and a fusible member fixed to the hole and arranged to establish an electrical connection with the electrode when the fusible member is fused to the electrode.

The fusible member is preferably solder. A portion of the circuit board surrounding the hole has preferably been removed. The flexible circuit board preferably further includes a conductive layer arranged on an inner surface of the hole. The conductive layer is preferably copper or a copper alloy. The electrode is preferably a conductive trace or a conductive plane. A mass of the fusible member is preferably formed on at least one side of the flexible circuit board. The electrode is preferably located on the surface of the flexible circuit board or within the flexible circuit board.

According to a preferred embodiment of the present invention, an electrical apparatus includes a target substrate and a flexible circuit board with a fusible member, where the flexible circuit board includes an electrode, a hole, and a fusible member fixed to the hole and arranged to establish an electrical connection with the electrode when the fusible member is fused to the electrode and where the fusible member is fused to form a joint between the flexible circuit board and the target substrate so that an electrical connection is formed between the electrode and the target substrate.

Other features, elements, characteristics, steps and advantages of the present invention will become more apparent from the following detailed description of preferred embodiments of the present invention with reference to the attached drawings.

### BRIEF DESCRIPTION OF THE DRAWINGS

FIG. 1 is a perspective view showing a series of steps taken to create a flexible circuit board according to a preferred embodiment of the present invention.

FIG. 2 is a top plan view showing the flexible circuit board shown in FIG. 1.

FIG. 3 is a side prospective view showing the flexible circuit board shown in FIG. 1.

FIG. 4 is a perspective view showing a flexible circuit board according to a preferred embodiment of the present invention.

FIG. 5 is a top plan view showing the flexible circuit board shown in FIG. 4.

FIG. 6 is a side prospective view showing the flexible circuit board shown in FIG. 4.

FIG. 7 is a top plan view showing a flexible circuit board according to a preferred embodiment of the present invention.

FIG. 8 is a side view showing a flexible circuit board attached to a target substrate according to a preferred embodiment of the present invention.

### DETAILED DESCRIPTION OF PREFERRED EMBODIMENTS

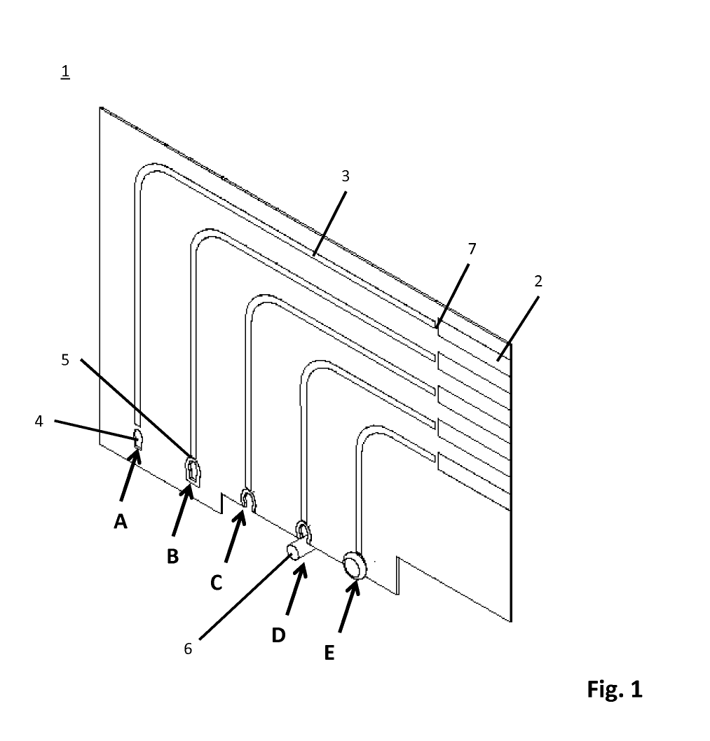

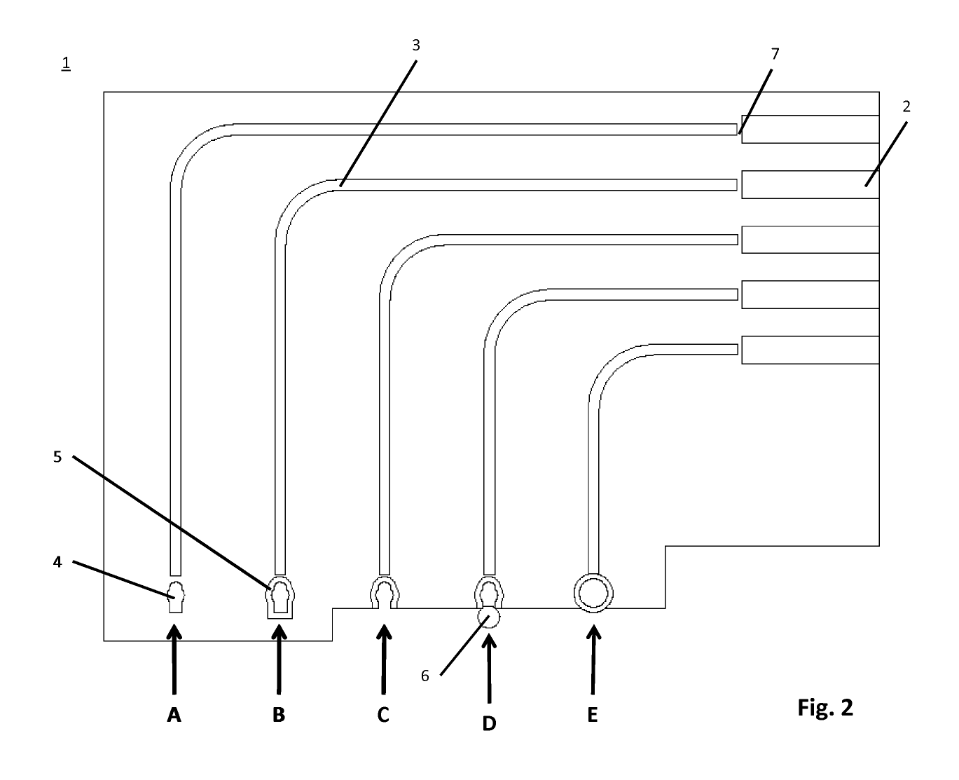

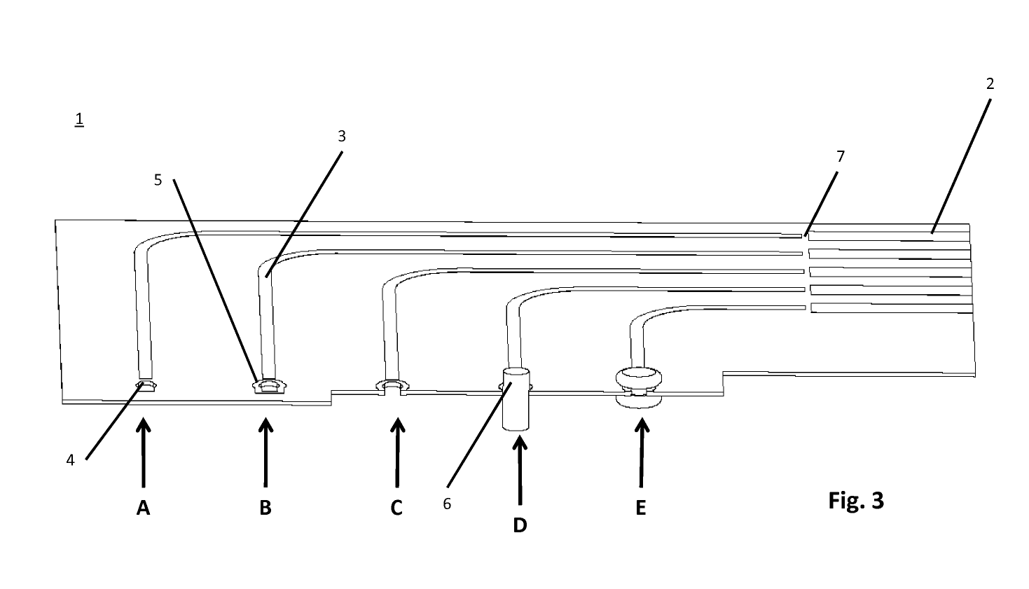

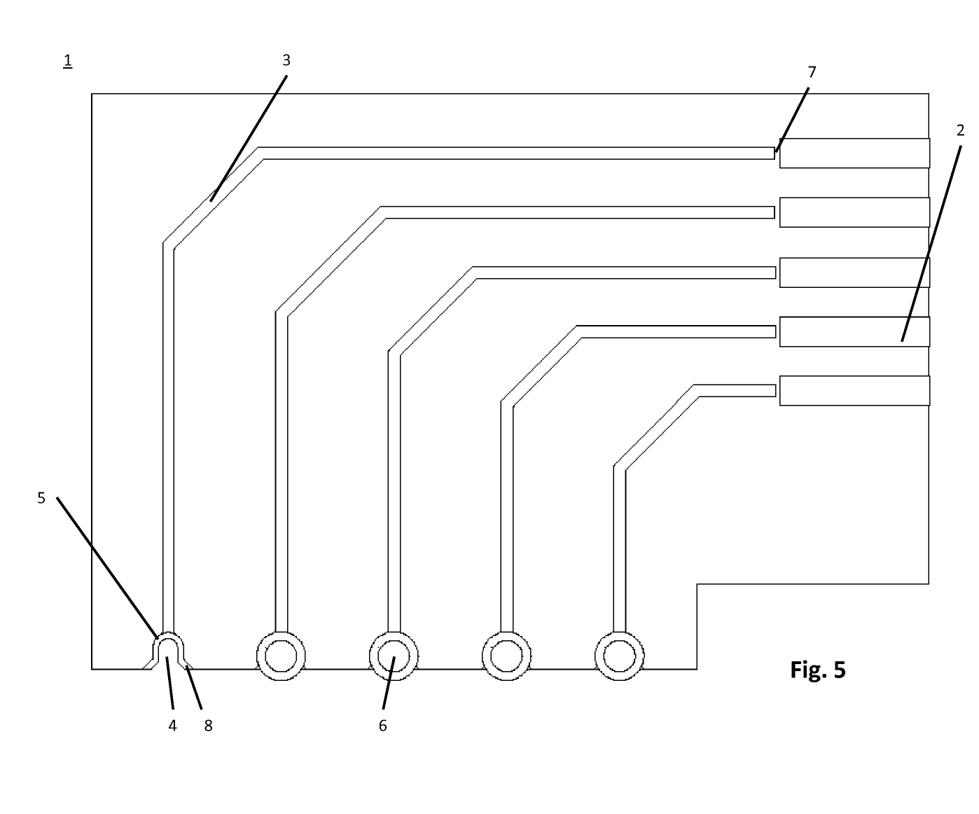

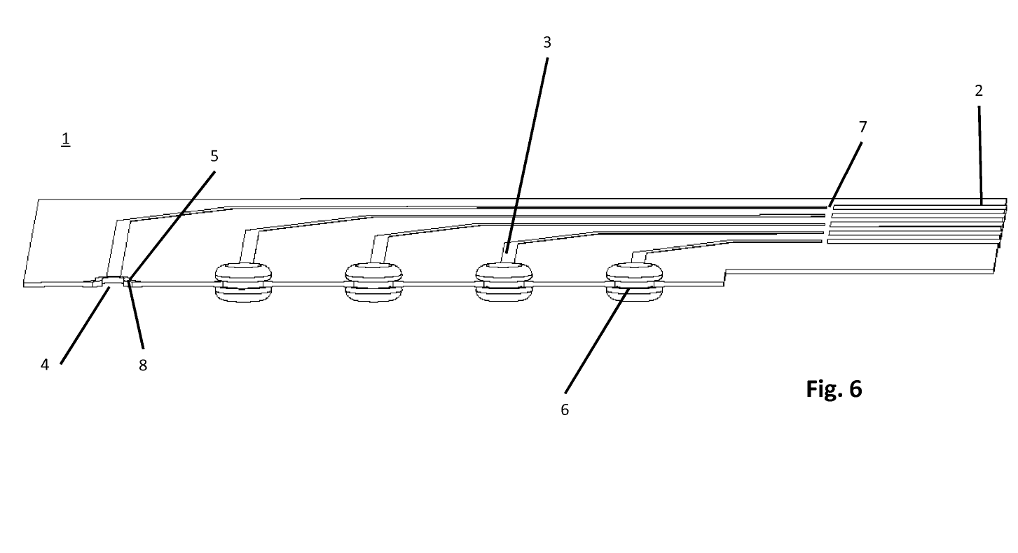

Preferred embodiments of the present invention are described with reference to FIGS. 1-8.

By eliminating the need to add solder to an electrical contact or any other structure to the flexible circuit board and by directly attaching solder to the flexible circuit board, a flexible circuit board according to the preferred embodiments of the present invention can be directly attached to a target substrate (typically a rigid circuit board but which can be any other suitable device) in a shorter time, with fewer components, and with fewer manufacturing steps.

By applying solder directly to the flexible circuit board so that the flexible circuit board can be soldered directly to the target substrate, fewer components and fewer processing steps are used, which saves manufacturing costs. Accordingly, it is possible to lower manufacturing costs by eliminating the need to add any electrical contacts or other structures to the flexible circuit board.

Crimping solder directly to the flexible circuit board permits the flexible circuit boards to be soldered directly by reflow oven processes, rather than using more complicated ultra-sonic welding or direct heat and pressure bonding processes. Additionally, because the flexible circuit boards are flexible and do not possess components with fixed geometries, flexible circuit boards permit easy re-positioning before soldering.

Flexible circuit board manufacturing processes in accordance with the preferred embodiments of the present invention can be designed in a much shorter time frame than traditional manufacturing processes using rigid printed circuit boards. Thus, manufacturing processes of preferred embodiments of the present invention provide much more customized spacing and arrangements. In addition, in conventional electrical connectors with stamped electrical contacts and rigid printed circuit boards, the possible location of the solder is fixed; however, the possible location of the solder on flexible circuit boards is variable.

Because the flexible circuit board manufacturing process performed in accordance with the preferred embodiments of the present invention can be designed for reel-to-reel continuous processing, attaching the solder with a flexible circuit board permits multiple manufacturing steps to be done at the same time, which increases the efficiency of batch processing when compared to conventional manufacturing processes. In reel-to-reel continuous processing, a reel of flexible circuit board material is processed at various stations where manufacturing steps can be performed. For example, one of the stations can form a conductive layer on a surface of the flexible circuit board material, and another of the stations can etch the conductive layer to form the conductive traces 3, shown in FIGS. 1-6. According to the preferred embodiments of the present invention, one or more stations can be added in which the Steps A-E, discussed below, can be performed. It is also possible to modify an existing station to perform one or more of the Steps A-E.

FIGS. 1-3 show five Steps A-E that are preferably preformed in creating a crimped solder connection in accordance with the preferred embodiments of the present invention. FIGS. 1-3 show different views of flexible circuit board 1. FIGS. 1-3 show a printed circuit board 1 preferably having an “L” shape; however, any other desirable shape can be used. The flexible circuit board 1 includes terminals 2 connected to corresponding conductive traces 3. FIGS. 1-3 show insulating coverfilms 7 covering the end of the conductive traces 3 where the conductive traces 3 contact the terminals 2. However, it is possible to not use these insulating coverfilms 7. FIGS. 1-3 show five electrical contacts 2 connected to five conductive traces 3, but any number of terminals 2 and any number of conductive traces 3 can be used in any desirable configuration.

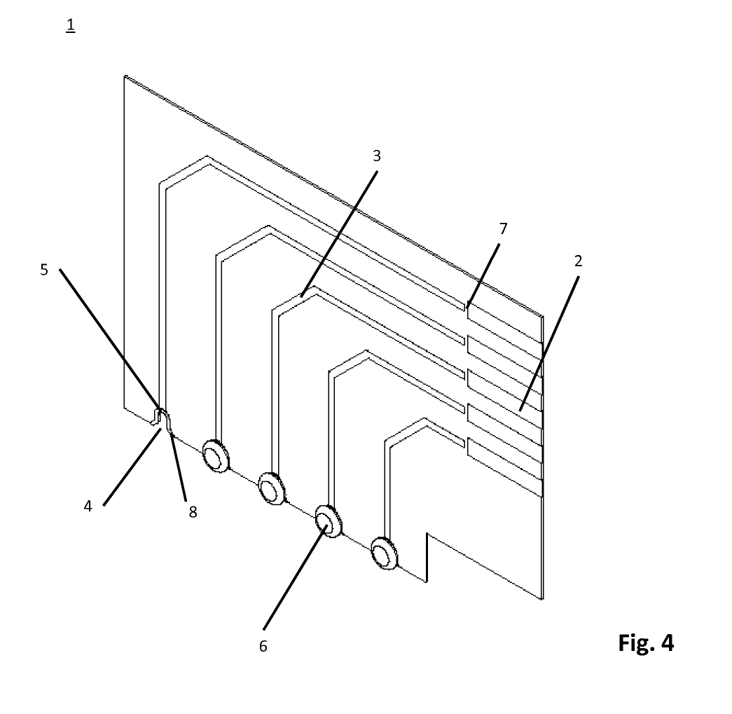

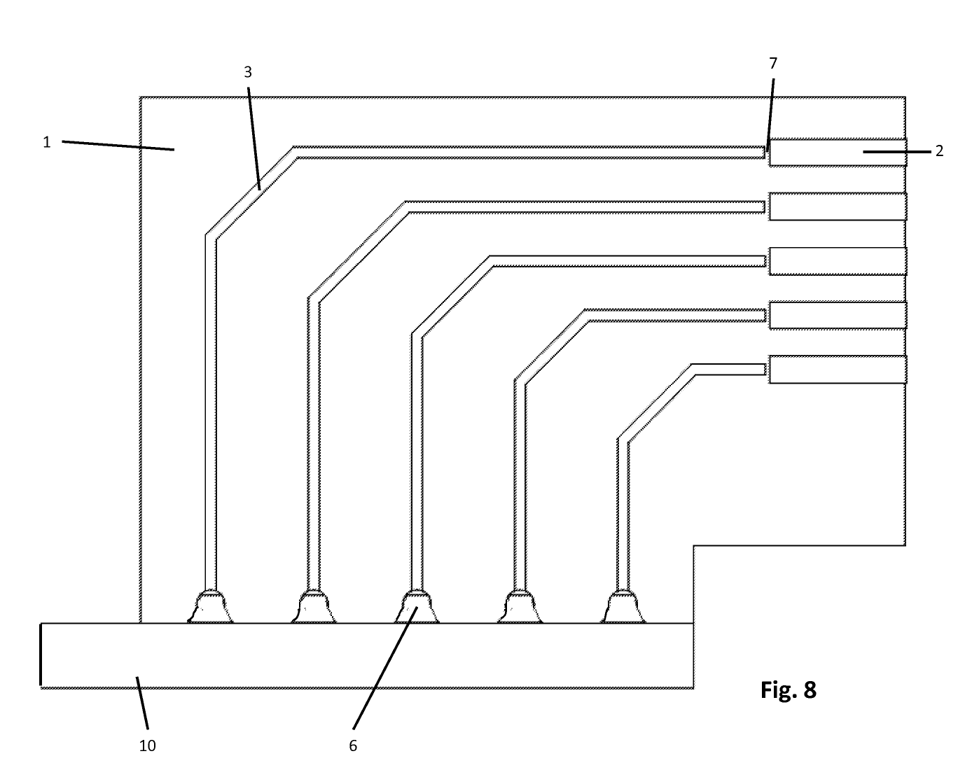

In Step A shown in FIGS. 1-3, a hole 4 is formed in the flexible circuit board 1. Preferably, the hole 4 has a circular or substantially circular shape, for example. It also possible to form the hole 4 with lead-ins 8, as shown in FIGS. 4-6, which help during Step D, discussed below, when the fusible member 6 is inserted into the hole 4. It is also possible to form the hole 4 with any other suitable shape, e.g. rectangular if the fusible member 6 is a solder tape with a rectangular cross-section. The hole 4 is located and shaped such that, when the fusible member 6 discussed in Steps D and E is reflowed, the fusible member 6 makes electrical connection to the conductive trace 3 and makes a sufficiently strong mechanical connection to the target substrate 10 shown in FIG. 8. Hole 4 can be formed by a punch, drill, or any other desirable manufacturing process. Hole 4 is preferably formed near the vicinity of a conductive trace 3, either at an end or the middle of the conductive trace 3. However, it is also possible to first form the hole 4 and then form the conductive trace 3 if the conductive trace 3 is located on the exterior of the flexible circuit board 1.

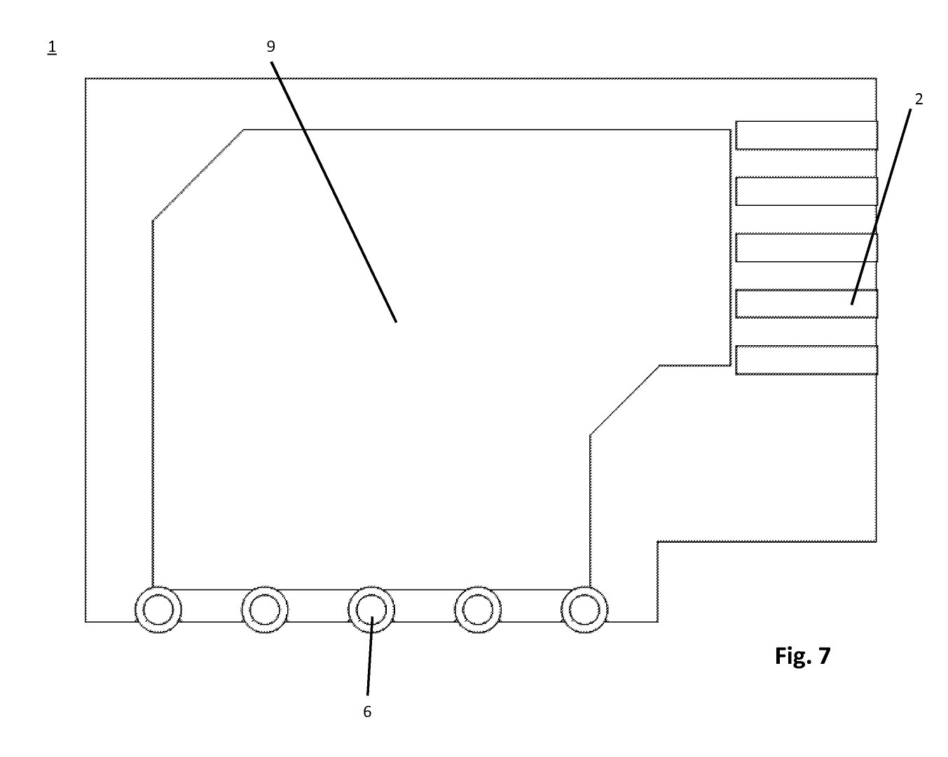

For clarity, FIGS. 1-3 show the conductive traces 3 on an exterior surface of the flexible circuit board 1. However, it is also possible that some or all of the conductive traces 3 are located within the flexible circuit board 1. It is also possible that hole 4 is formed in or near any electrode on or within the flexible circuit board, including a conductive plane 9 as shown in FIG. 7, which can be located either on the exterior of or within the flexible circuit board 1. The conductive plane 9 could be used as either a ground plane or a power plane. Depending upon the application, the flexible circuit board 1 can include conductive traces 3 on some layers and can include conductive planes on other layers. It should be understood that the fusible member 6 can be used to make an electrical connection with a conductive plane in a similar manner as the fusible member 6 makes an electrical connection to the conductive trace 3. It is also possible that the flexible circuit board 1 includes electrical components. The electrical components can be either passive or active electrical components and can be attached to a surface of the flexible circuit board 1 or embedded within the flexible circuit board 1.

After forming the hole 4 in the flexible circuit board 1, in Step B, a conductive layer 5 is formed within the inner surface and around the outer perimeter of the hole 4. The conductive layer 5 is preferably copper or a copper alloy, but any other suitable electrically conductive material can be used. It is also possible to form more than one conductive layer, with the additional conductive layers (not shown) having the same composition or different composition as the first conductive layer. The conductive layer 5 is applied by, for example, etching, priming, reflowing, electroplating, welding, gluing, sticking, or any other suitable process. The conductive layer 5 is preferably formed to be electrically connected to the conductive trace 3. However, it is possible that the conductive layer 5 is formed such that an electrical connection will not be established until the fusible member 6 is deformed in Step E. It is also possible to skip Step B such that the conductive layer 5 is not formed within or around the hole 4 so long as the fusible member 6 discussed in Steps D and E establishes an electrical connection to the conductive trace 3.

Then, in Step C, a portion of the outer perimeter of the hole 4 is removed along a chord of the hole 4 such that the hole 4 is no longer closed. It is possible to reverse Steps B and C such that the conductive layer 5 is not formed until after a portion of the hole 4 has been removed. The removal of a portion of the hole 4 is performed such that, when the fusible member 6 discussed in Steps D and E is reflowed, the fusible member 6 makes electrical connection to the conductive trace 3 and makes a sufficiently strong mechanical connection to the target substrate 10 shown in FIG. 8. The removal of the hole 4 can be performed by, for example, cutting off, shearing, tearing, opening, or any other desirable removal process. It is possible to skip Step C so that the fusible member 6 is inserted into a hole 4 that has not been cut. However, it is preferably not to skip Step C because having an open hole 4 allows for easier insertion of the fusible member 6 in Step D because the fusible member 6 does not have to be threaded through the hole 4, allows for less fusible member 6 to be used because the center of mass of the fusible member 6 can be closer to the target substrate 10 shown in FIG. 8, allows for a smaller pitch between the conductive traces 3 because less fusible member 6 is used, and allows for faster processing time because less fusible member 6 is used.

Next, in Step D, a length of fusible member 6 is inserted into the hole 4 and cut to length. Is it also possible to cut the fusible member 6 and then inserted in the hole 4. The fusible member 6 can be, for example, reflowable wire, solder wire, resin core solder, or any other desirable fusible member.

After the fusible member 6 is inserted into the hole 4, in Step E, the fusible member 6 is deformed such that the fusible member 6 is fixed within the hole 4. This deformation process is preferably a crimping or compression process. The fusible member 6 is typically deformed such that two masses of the fusible member are formed, with one of the masses formed on each side of the flexible circuit board 1, forming a “double-donut” or “landing-gear” shape. It is also possible that a mass is only formed on one side of the flexible circuit board 1, forming a “mushroom” shape. Thus, after being fixed to the flexible circuit board 1, the fusible member 6 will be close enough to a surface of the target substrate 10 such that the fusible member 6 will form a joint of sufficient strength when the fusible member 6 is reflowed through, for example, an oven reflow process.

Above, the Steps A-E are described with respect to the attachment of a single fusible member 6. Typically, multiple fusible members 6 are attached per flexible circuit board 1. It is possible to sequentially perform Steps A-E for each fusible member 6: Step A, . . . , Step E, . . . , Step A, . . . , Step E. It is also possible to repeatedly perform Steps A-E for each fusible member 6: Step A, . . . , Step A, . . . , Step E, . . . Step E. It is also possible to sequentially perform some steps and to repeatedly perform other steps.

FIGS. 4-6 show an example of a flexible circuit board 1 in accordance with a preferred embodiment of the present invention. FIGS. 4-6 show different views of the flexible circuit board 1. The flexible circuit board 1 includes a plurality of fusible members 6 which have been deformed to fix the fusible member 6 in the holes 4 that typically include conductive layers 5. The holes 4 in FIGS. 4-6 include lead-ins 8 that allow for easier insertion of the fusible member 6. Although FIGS. 4-6 show a printed circuit board 1 having an “L” shape, any other desirable shape can be used. Further, the flexible circuit board 1 can include any number of terminals 2 and any number of conductive traces 3 arranged in any suitable arrangement.

FIG. 7 shows a flexible circuit board 1 with a conductive plane 9 provided on an exterior surface of the flexible circuit board 1. The conductive plane 9 can be connected to one or more fusible member 6 and can be connected to one or more of the terminals 2.

FIG. 8 shows a flexible circuit board 1 connected to a target substrate 10 by fusible members 6. The flexible circuit board 1 establishes an electrical connection between the target substrate 10 and the terminals 2 through electrical traces 3. Typically, an electrical connector (not shown) is connected to the side of the flexible circuit board 1 with the terminals 3.

The flexible circuit board 1 according to preferred embodiments of the present invention can be directly attached to a target substrate 10 through the fusible member 6 without requiring any intervening engagement element.

Thus, by directly connecting a fusible member to a flexible circuit board in accordance with preferred embodiments of the present invention, it is possible to:

1) shorten the manufacturing process and provide a quicker design cycle for each product, which reduces the labor costs and increases the capacity per every manufacturing process of a complete system;

2) lower manufacturing costs (even at lower volumes of manufacturing), reduce number of components, and reduce manufacturing steps;

3) enhance manufacturing and performance by providing a flexible circuit board that can be folded and moved around during both processing and manufacturing;

4) provide greatly reduced performance limitations by allowing the solder and the circuitry to vary infinitely permits significantly greater flexibility in connector design geometry; and

5) provide a greater number of transmission lines, higher density, and greater complexity because of the thinness of the flexible circuit board.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A method for attaching a fusible member to a flexible circuit board comprising:
providing the flexible circuit board including an electrode and a hole near each other;
placing the fusible member in the hole; and
deforming the fusible member to fix the fusible member to the flexible circuit board.

2. The method for attaching a fusible member to a flexible circuit board of claim 1, wherein the fusible member is solder.

3. The method for attaching a fusible member to a flexible circuit board of claim 1, wherein the deforming step is performed by crimping the fusible member.

4. The method for attaching a fusible member to a flexible circuit board of claim 1, wherein a portion of the flexible circuit board surrounding the hole is removed prior to the step of placing the fusible member into the hole.

5. The method for attaching a fusible member to a flexible circuit board of claim 1, further comprising forming a conductive layer to an inner surface of the hole.

6. The method for attaching a fusible member to a flexible circuit board of claim 5, wherein the conductive layer is copper or a copper alloy.

7. The method for attaching a fusible member to a flexible circuit board of claim 1, wherein the electrode is a conductive trace or a conductive plane.

8. The method for attaching a fusible member to a flexible circuit board of claim 1, wherein, during the step of deforming, a mass of the fusible member is formed on at least one side of the flexible circuit board.

9. The method for attaching a fusible member to a flexible circuit board of claim 1, wherein the electrode is located on the surface of the flexible circuit board or within the flexible circuit board.

10. A method for electrically connecting a flexible circuit board to a target substrate comprising:
providing a target substrate;
providing a flexible circuit board with a fusible member according to claim 1; and
fusing the fusible member to form a joint between the flexible circuit board and the target substrate so that an electrical connection is formed between the electrode and the target substrate.

11. A flexible circuit board comprising:
an electrode;
a hole; and
a fusible member fixed to the hole and arranged to establish an electrical connection with the electrode when the fusible member is fused to the electrode.

12. The flexible circuit board of claim 11, wherein the fusible member is solder.

13. The flexible circuit board of claim 11, wherein a portion of the circuit board surrounding the hole has been removed.

14. The flexible circuit board of claim 11, further comprising a conductive layer arranged on an inner surface of the hole.

15. The flexible circuit board of claim 14, wherein the conductive layer is copper or a copper alloy.

16. The flexible circuit board of claim 11, wherein the electrode is a conductive trace or a conductive plane.

17. The flexible circuit board of claim 11, wherein a mass of the fusible member is formed on at least one side of the flexible circuit board.

18. The flexible circuit board of claim 11, wherein the electrode is located on the surface of the flexible circuit board or within the flexible circuit board.

19. An electrical apparatus comprising:
a target substrate; and
a flexible circuit board with a fusible member according to claim 1; wherein
the fusible member is fused to form a joint between the flexible circuit board and the target substrate so that an electrical connection is formed between the electrode and the target substrate.
